(19) United States
(12) Patent Application Publication
(10) Pub. No.: US 2011/0095817 A1
(43) Pub. Date: Apr. 28, 2011

(54) OVERCURRENT DETECTION CIRCUIT AND SIGNAL AMPLIFYING DEVICE

(75) Inventor: Toshimi YAMADA, Miyazaki (JP)

(73) Assignee: OKI SEMICONDUCTOR CO., LTD., Tokyo (JP)

(21) Appl. No.: 12/900,237

(22) Filed: Oct. 7, 2010

(30) Foreign Application Priority Data
Oct. 22, 2009 (JP) 2009-243666

(51) Int. Cl. H03F 1/34; H02H 9/02

(52) U.S. Cl. 330/98; 361/93.1

(57) ABSTRACT

Disclosed is a signal amplifying device which includes an overcurrent detection circuit, a first inverting amplifying circuit amplifying an input signal, and a second inverting amplifying circuit amplifying an output of the first inverting amplifying circuit. The overcurrent detection circuit includes a comparison circuit and a decision circuit. The comparison circuit compares the voltage of the input signal with the voltage of an output of the second inverting amplifying circuit, and generates a signal responsive to the comparison result. The decision circuit detects overcurrent from the signal output by the comparison circuit.

### BACKGROUND OF THE INVENTION

1. Field of the Invention

The present invention relates to techniques for detecting overcurrent due to an impedance fault in a load that is provided with an electrical signal.

2. Description of the Related Art

In audio equipment and the like, if a load such as a loudspeaker (simply ‘speaker’ below) is short-circuited, the resultant flow of overcurrent may damage the amplifier and other circuits that are connected to and supply signals to the load. Overcurrent detection is used to avoid such damage.

In Japanese Patent Application Publication No. 2001-4674, a current supply circuit for supplying current from a power source to a load is disclosed. The current supply circuit also generates an electric current proportional to the current supplied to the load, and detects overcurrent by comparing a voltage level obtained by integration of this proportional current with a prescribed reference voltage. A problem with this overcurrent detection method is that it is difficult to set an appropriate reference voltage when the load current varies irregularly.

In Japanese Patent Application Publication No. 2008-5009, a signal amplifying device that detects short circuits in a speaker load is disclosed. This device includes a signal amplifier for supplying an amplified signal to a speaker terminal, an internal power source for outputting a prescribed voltage through a resistor to the speaker terminal, a switching circuit for switchably connecting the signal amplifier and internal power source to the speaker terminal, and a microcontroller. Before the amplified signal is supplied to the speaker, the signal amplifier is disconnected, the internal power source is connected, and the microprocessor monitors the voltage level at the speaker terminal. If the monitored voltage level consistently exceeds a threshold value, indicating a high speaker impedance, the internal power source is disconnected and the signal amplifier is connected to the speaker terminal; if the monitored voltage drops below the threshold, indicating a short circuit in the speaker, the signal amplifier is left disconnected from the speaker terminal and the internal power source is also disconnected. A problem is that the amplified audio signal cannot be supplied to the speaker during the overcurrent test, and conversely, short circuits and other speaker faults cannot be detected during normal operation.

### SUMMARY OF THE INVENTION

An object of the present invention is to provide an overcurrent detection circuit and signal amplifying device that can detect overcurrent due to a change or fault in load impedance even while an amplified signal with a varying voltage level is being supplied to the load.

According to a first aspect of the invention, an overcurrent detection circuit for detecting overcurrent due to an impedance fault between first and second input terminals of a load is provided. The first input terminal of the load is connected to an output terminal of a first inverting amplifying circuit that amplifies an input signal, and the second input terminal of the load is connected to an output terminal of a second inverting amplifying circuit (10) that amplifies an output of the first inverting amplifying circuit. The overcurrent detection circuit includes a comparison circuit and a decision circuit.

The comparison circuit compares a voltage of the input signal with a voltage of an output of the second inverting amplifying circuit, and generates a signal responsive to a result of the comparison. The decision circuit detects the overcurrent from the signal output by the comparison circuit. Overcurrent due to an impedance fault in the load can thereby be detected while the load is operating.

According to a second aspect of the invention, a signal amplifying device including the overcurrent detection circuit described above and a signal amplifier is provided. The signal amplifier includes the first and second inverting amplifying circuits.

By comparing the voltages of the input signal and the output of the second inverting amplifying circuit, the overcurrent detection circuit is able to detect overcurrent accurately even while amplified signals with voltage levels that vary irregularly are being supplied to the load.

### BRIEF DESCRIPTION OF THE DRAWINGS

In the attached drawings:

FIG. 1 schematically illustrates an exemplary signal amplifying device and speaker load in a first embodiment of the invention;

FIG. 2 is a waveform diagram schematically illustrating signal voltage waveforms during normal operation of the speaker load in the first embodiment;

FIG. 3 is a waveform diagram schematically illustrating signal voltage waveforms during abnormal operation of the speaker load in the first embodiment;

FIG. 4 schematically illustrates an exemplary signal amplifying device and speaker load in a second embodiment; and

FIG. 5 schematically illustrates an exemplary signal amplifying device and speaker load in a third embodiment.

### DETAILED DESCRIPTION OF THE INVENTION

Embodiments of the invention will now be described with reference to the attached drawings, in which like elements are indicated by like reference characters. Reference characters V_{IN}, V1, V2, and V_{CR} are used to designate both signals and the voltage levels of these signals.

### First Embodiment

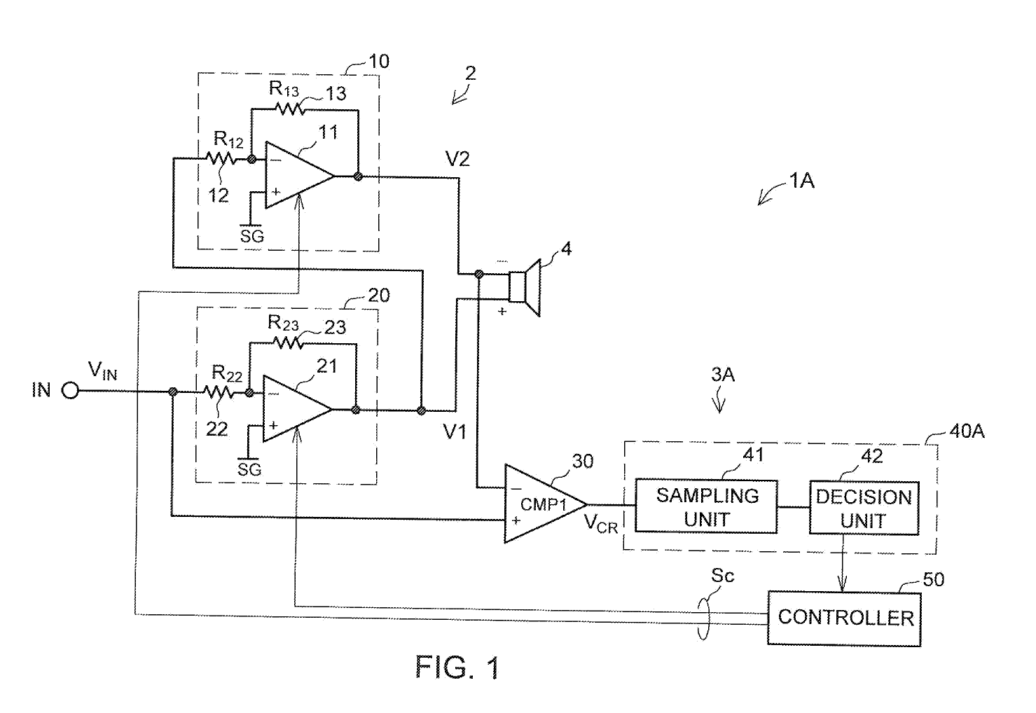

Referring to FIG. 1, the signal amplifying device 1A in the first embodiment includes a signal amplifier 2 comprised of a pair of inverting amplifying circuits 10, 20; an overcurrent detection circuit 3A; a speaker (load) 4; and a controller 50.

The signal amplifier 2 has an input terminal IN that receives an audio signal V_{IN} from an external source (not shown). Inverting amplifying circuit 20 amplifies the received audio signal and outputs a voltage signal V1 whose phase is inverted relative to the input audio signal V_{IN}. The output terminal of inverting amplifying circuit 20 is connected to the positive (+) input terminal of the speaker 4, referred to below as the positive speaker terminal.

The output terminal of inverting amplifying circuit 20 is the output terminal of an operational amplifier (op-amp) 21 that forms the active component of amplifying circuit 20. Op-amp 21 also has an inverting input terminal (−) connected to the input terminal IN via an input resistance element 22 having a resistance value R₂₂ and a non-inverting input terminal (+) biased at a reference voltage SG. In the present embodiment, the reference voltage SG about half the power supply voltage VDD (not shown). The output terminal and inverting input terminal of op-amp 21 are connected via a feedback resistance element 23 having a resistance value R₂₃ to form a negative feedback loop. The resistance values R₂₂, R₂₃ of resistance elements 22 and 23 are selected so that the voltage gain of inverting amplifying circuit 20 is unity.

Inverting amplifying circuit 10 amplifies the output of inverting amplifying circuit 20 and supplies a voltage signal V2 to the negative (−) input terminal of the speaker 4, referred to below as the negative speaker terminal. Inverting amplifying circuit 10 is similar to amplifying circuit 20, including an op-amp 11 with inverting (−) and non-inverting (+) input terminals. The non-inverting input terminal is biased at the reference voltage SG. The inverting input terminal is connected to the output terminal of inverting amplifying circuit 20 via an input resistance element 12 having a resistance value R₁₂, and to the output terminal connected of op-amp 11 via a feedback resistance element 13 having a resistance value R₁₃, forming a feedback loop. Voltage signal V2 is output from the output terminal of op-amp 11. The resistance values R₁₂, R₁₃ of resistance elements 12 and 13 are selected so that the voltage gain of inverting amplifying circuit 10 is also unity.

The speaker 4 operates according to the voltage difference ΔV (=V1−V2) between the voltages at its positive (+) and negative (−) terminals. When the internal circuitry (not shown) of the speaker 4, including internal resistance elements, is operating normally, the impedance between the positive and negative speaker terminals is high and the flow of current therebetween is effectively limited. In addition, since the phase of the voltage signal V2 output from inverting amplifying circuit 10 is inverted relative to the voltage signal V1 output from inverting amplifying circuit 20, the voltage V2 at the negative speaker terminal is in phase with the input voltage V_{IN}. Since both inverting amplifying circuits 10, 20 have unity voltage gain, the difference between voltages V2 and V_{IN} is substantially zero.

If an internal circuit fault in the speaker 4 reduces the impedance between the positive and negative speaker terminals, overcurrent may flow on a path from inverting amplifying circuit 10 to inverting amplifying circuit 20 through the speaker 4. A circuit fault that reduces the impedance at just one of the two speaker terminals may also occur, dropping the voltage at the faulty speaker terminal to a low level and causing overcurrent to flow in the inverting amplifying circuit 10 or 20 connected to that speaker terminal.

Any such reduction in the impedance of the speaker 4 changes the absolute value (|ΔVi|) of the voltage difference ΔVi (=V_{IN}−V2) between the voltage V2 at the negative speaker terminal and the input voltage V_{IN}. In order to detect overcurrent from this voltage difference ΔVi, the overcurrent detection circuit 3A uses a comparator (CMP1) 30 as a comparison circuit and has a decision circuit 40A. The comparator 30 compares the input voltage V_{IN} with voltage V2 and outputs a bi-level voltage signal V_{CR} at a high or low logic level responsive to the comparison result, that is, responsive to the voltage difference ΔVi. The decision circuit 40A has a sampling unit 41 and a decision unit 42 that detect overcurrent on the basis of the comparison result signal V_{CR}.

The comparator 30 has an inverting (−) input terminal that receives voltage V2, a non-inverting (+) input terminal that receives the input voltage V_{IN}, and an output terminal from which the comparison result signal V_{CR} is output. In the present embodiment, the comparator 30 is a Schmitt trigger comparator with two threshold values Vth1, Vth2, where Vth2 is less than Vth1. The comparison result signal V_{CR} exhibits hysteresis, going high when ΔVi is above Vth1, going low when ΔVi is below Vth2, and remaining at its current level when ΔVi is between Vth1 and Vth2.

When the impedance of the speaker 4 is high and the comparison result signal V_{CR} is at the low logic level, even if the voltage difference ΔVi fluctuates somewhat, V_{CR} remains at the low logic level as long as ΔVi remains below Vth1. If a drop in the impedance of the speaker 4 sends the voltage difference ΔVi above Vth1, the comparator 30 switches comparison result signal V_{CR} from the low logic level to the high logic level and holds the comparison result signal V_{CR} at the high logic level until ΔVi falls back to a value equal to or less than Vth2.

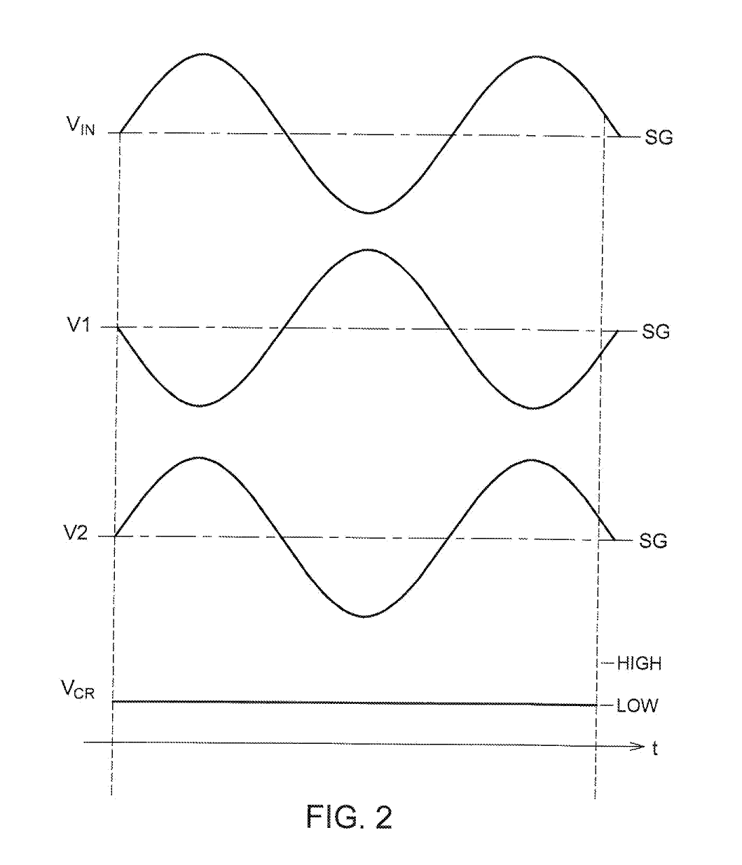

FIG. 2 shows voltage waveforms of the input audio signal V_{IN}, the signal V1 input to the positive speaker terminal, the signal V2 input to the negative speaker terminal, and the comparison result signal V_{CR} output from the comparator 30 during normal operation of the speaker 4. The input waveform V_{IN} is assumed for convenience to be a sine wave; the voltage waveform of an actual audio signal may vary irregularly. Regardless of how V_{IN} varies, the V_{IN} and V2 waveforms are substantially identical and comparison result signal V_{CR} remains at the low logic level.

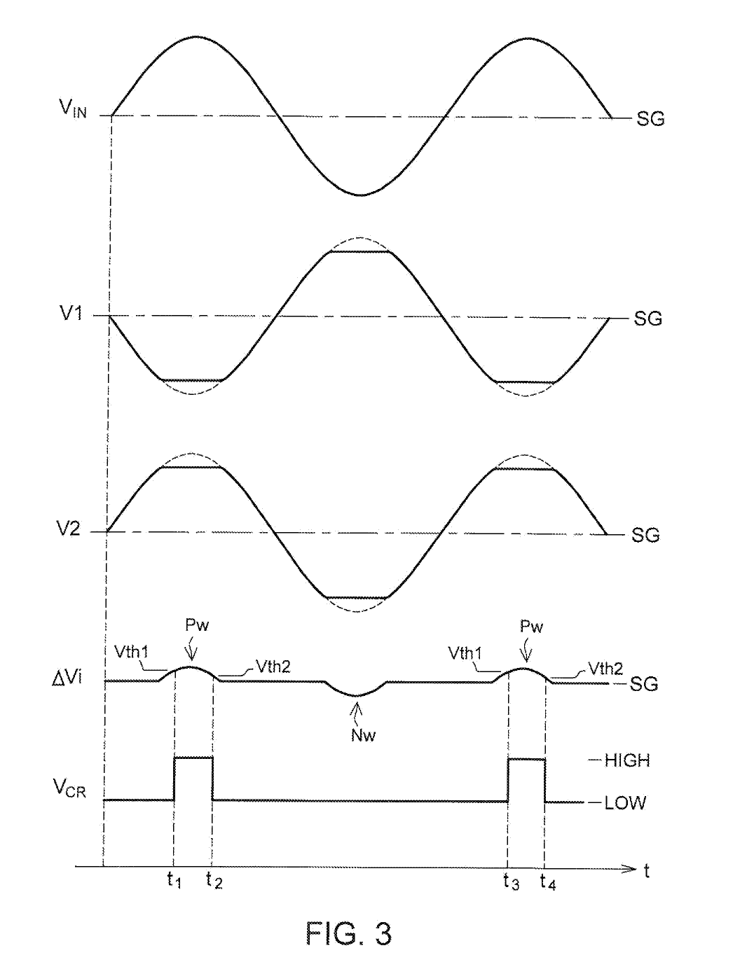

FIG. 3 shows waveforms of V_{IN}, V1, V2, the voltage difference ΔVi (=V_{IN}−V2), and the comparison result signal V_{CR} when the impedance of the speaker 4 is abnormally low. The V1 and V2 waveforms are distorted. In the parts Pw of the ΔVi waveform corresponding to positive peaks in the V2 waveform, the voltage difference ΔVi exceeds the first threshold value Vth1. The comparator 30 switches the comparison result signal V_{CR} from the low to the high logic level at times t₁ and t₃, when ΔVi crosses the first threshold level Vth1, and holds V_{CR} at the active (high) level until ΔVi falls back to the second threshold value Vth2. In the example shown, the comparison result signal V_{CR} goes low at times t₂ and t₄.

In FIG. 3, the first and second threshold values Vth1, Vth2 both have positive values. In a variation of the first embodiment, the first and second threshold values Vth1, Vth2 both have negative values (where Vth1 is less than Vth2), and the comparator 30 detects distorted negative peaks of the V2 waveform, corresponding to the part Nw of the voltage difference waveform ΔVi in FIG. 3.

In the decision circuit 40A, the sampling unit 41 continuously samples the output of the comparator 30 and supplies data indicating the level of the comparison result signal V_{CR} to the decision unit 42 as sampling results. The decision unit 42 detects the occurrence of the high logic level in at least a certain number of consecutive samples as indicating overcurrent attributable to abnormal low impedance in the speaker 4.

Upon detecting the occurrence of the overcurrent from the samples of the comparison result signal V_{CR}, the decision unit 42 notifies the controller 50. The controller 50 responds by sending control signals Sc to the inverting amplifying circuits 10 and 20 that temporarily halt their operation. Specifically, the control signals Sc place switching transistors (not shown) in op-amps 11 and 21 in the non-conducting state. These switching transistors may be, for example, p-type or n-type metal-oxide-semiconductor (MOS) transistors. This temporary shutdown prevents the signal amplifier 2 from malfunctioning due to overcurrent.

Since the overcurrent detection circuit 3A in the first embodiment detects overcurrent from the voltage difference between the input signal voltage V_{IN} and the amplified voltage V2, which normally have the same shape, overcurrent due to impedance changes in the speaker 4 can be monitored even if the input signal voltage V_{IN} varies irregularly.

### Second Embodiment

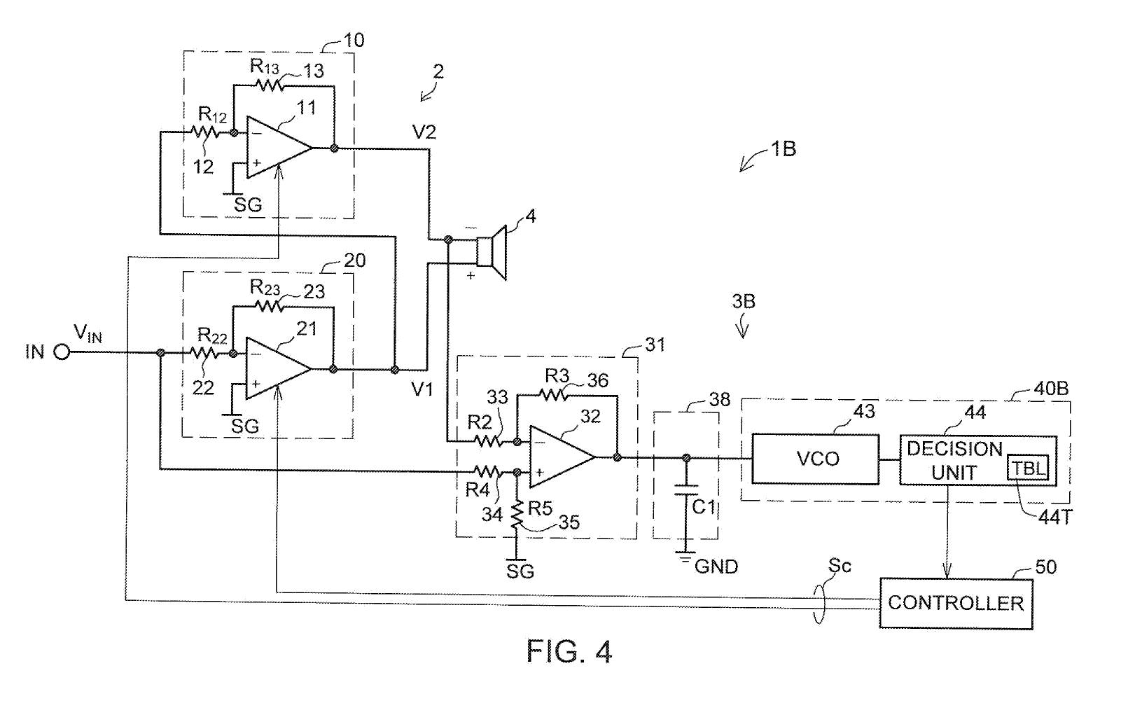

Referring to FIG. 4, the signal amplifying device 1B in the second embodiment includes a signal amplifier 2 and an overcurrent detection circuit 3B, both of which are connected to a speaker 4, and a controller 50. The signal amplifier 2, speaker 4, and controller 50 are similar to the corresponding elements in the first embodiment.

The overcurrent detection circuit 3B includes a differential amplifier circuit 31, a filter circuit 38, and a decision circuit 40B. The differential amplifier circuit 31 amplifies the voltage difference ΔVi (=V_{IN}−V2) between the input voltage V_{IN} and the voltage V2 at the negative speaker terminal. The filter circuit 38 smoothes or filters the output voltage of the differential amplifier circuit 31. The differential amplifier circuit 31 and filter circuit 38 constitute a comparison circuit for comparing the input voltage V_{IN} with the voltage V2 and outputting a signal responsive to the comparison result.

As shown in FIG. 4, the differential amplifier circuit 31 includes an op-amp 32. The op-amp 32 has an inverting input terminal (−) connected to the negative speaker terminal via an input resistance element 33 having a resistance value R2, a non-inverting input terminal (+) that receives the input signal V_{IN} via an input resistance element 34 having a resistance value R4 and the reference voltage SG via a resistance element 35 having a resistance value R5, and an output terminal connected to the inverting input terminal (−) via a feedback resistance element 36 having a resistance value R3.

If, for example, resistance values R4 and R5 are respectively equal to resistance values R2 and R3, the output voltage V_{D} of the differential amplifier circuit 31 is given by the equation

V_{D}=(R3/R2)×(V_{IN}−V2)+SG.

Therefore, when the input terminal IN receives an audio signal V_{IN} having a sine waveform as in FIG. 3, the differential amplifier circuit 31 amplifies and outputs the voltage difference ΔVi indicated in FIG. 3.

The filter circuit 38 in FIG. 4 includes a capacitor C1 connected between the output terminal of the op-amp 32 in the differential amplifier circuit 31 and ground (GND). The normal output voltage level of the filter circuit 38 can be adjusted by designing the differential amplifier circuit 31 to produce an offset voltage when V_{IN} and V2 are equal. The offset voltage can be set to a desired value by, for example, adjusting the resistance ratio (R4/R5) of the resistors connected to the non-inverting input terminal of op-amp 32, or by designing the input transistors (not shown) connected to the inverting and non-inverting input terminals of op-amp 32 to produce different drain currents when V_{IN} and V2 are equal.

The decision circuit 40B includes a voltage-controlled oscillator (VCO) 43 operating as a voltage-to-frequency converter and a decision unit 44. The voltage-controlled oscillator 43 outputs an oscillation signal having a frequency corresponding to the output voltage of the filter circuit 38. The decision unit 44 converts the oscillation signal to a train of pulses and counts the number of pulses per unit time to obtain a data value indicating the frequency of the oscillation signal. The decision unit 44 can then convert this frequency data value to a value indicating the overcurrent magnitude by referring to a look-up table (TBL) 44T in which a correspondence relationship between frequency and overcurrent magnitude is prestored. In place of the look-up table 44T, a mathematical formula may be used to calculate the overcurrent magnitude from the frequency data value.

Upon detecting the occurrence of overcurrent, the decision unit 44 notifies the controller 50. As in the first embodiment, the controller 50 responds with output of control signals Sc that temporarily shut down the inverting amplifying circuits 10, 20.

As in the first embodiment, the overcurrent detection circuit 3B in the second embodiment can monitor the presence or absence of overcurrent even when the input signal V_{IN} and amplified signals V1, V2 have irregularly varying voltage levels. In addition, the overcurrent detection circuit 3B in the second embodiment converts the voltage difference ΔVi to frequency information and detects the magnitude of the overcurrent from the frequency information, so overcurrent can be detected more accurately than in the first embodiment.

### Third Embodiment

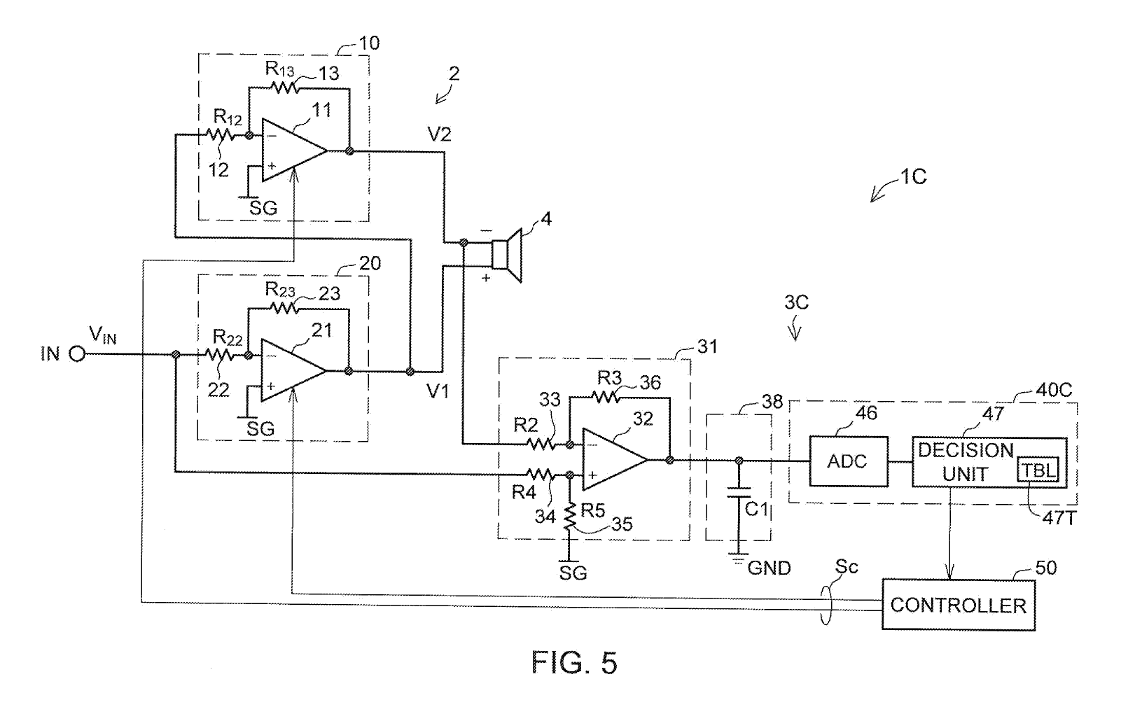

Referring to FIG. 5, the signal amplifying device 1C in the third embodiment comprises a signal amplifier 2 and an overcurrent detection circuit 3C, both of which are connected to a speaker 4, and a controller 50. The signal amplifier 2, speaker 4, and controller 50 in the signal amplifying device 1C are similar to the corresponding elements in the first embodiment. The overcurrent detection circuit 3C has the same configuration as in the second embodiment, except for the decision circuit 40C.

The overcurrent detection circuit 3C includes the differential amplifier circuit 31 and filter circuit 38 described in the second embodiment as well as the decision circuit 40C. The decision circuit 40C includes an analog-to-digital converter (ADC) 46 and a decision unit 47. The analog-to-digital converter 46 converts the output voltage of the filter circuit 38, which is an analog signal, to a digital signal. The decision unit 47 then detects the magnitude of overcurrent corresponding to the value of the digital signal by referring to a look-up table (TBL) 47T in which a correspondence relationship between the value of the digital signal and the overcurrent magnitude is prestored. In place of the look-up table 47T, a mathematical formula may be used to calculate the overcurrent magnitude from the value of the digital signal.

Upon detecting the occurrence of overcurrent, the decision unit 47 notifies the controller 50. As in the first embodiment, the controller 50 responds by sending control signals Sc that temporarily shut down the inverting amplifying circuits 10, 20.

As in the first embodiment, the overcurrent detection circuit 3C in the third embodiment can monitor the presence or absence of overcurrent even when the voltage levels of the input signal V_{IN} and amplified signals V1, V2 vary irregularly. In addition, the overcurrent detection circuit 3C in the third embodiment converts the voltage difference ΔVi to a digital signal and detects the magnitude of the overcurrent from the digital signal, so overcurrent can be detected more accurately than in the first embodiment. Furthermore, although neither the voltage-controlled oscillator 43 in the second embodiment nor the analog-to-digital converter 46 in the third embodiment produces an output that is completely faithful to the input voltage from the filter circuit 38, the deviations occurring in the output of the analog-to-digital converter 46 are smaller than the deviations in the output of the voltage-controlled oscillator 43, so the accuracy of overcurrent detection is higher in the third embodiment than in the second embodiment.

The invention is not limited to the embodiments described above and shown in the drawings. For example, the above embodiments detect overcurrent due to low impedance in a speaker, but similar embodiments can be used to detect overcurrent in loads other than speaker loads.

Those skilled in the art will recognize that further variations are possible within the scope of the invention, which is defined in the appended claims.

What is claimed is:

1. An overcurrent detection circuit for detecting overcurrent due to an impedance fault between first and second input terminals of a load, said first input terminal of said load being connected to an output terminal of a first inverting amplifying circuit that amplifies an input signal, and said second input terminal of said load being connected to an output terminal of a second inverting amplifying circuit that amplifies an output of said first inverting amplifying circuit, said overcurrent detection circuit comprising:
a comparison circuit for comparing a voltage of the input signal with a voltage of an output of said second inverting amplifying circuit, and generating a signal responsive to a result of the comparison; and
a decision circuit for detecting the overcurrent from the signal output by said comparison circuit.

2. The overcurrent detection circuit of claim 1, wherein:
the signal responsive to a result of the comparison is a bi-level signal; and
said decision circuit includes:
a sampling unit for sampling the signal output by said comparison circuit; and
a decision unit for detecting the overcurrent from the sampled signal.

3. The overcurrent detection circuit of claim 2, wherein:
said comparison circuit includes a comparator for generating the bi-level signal by switching a voltage level of an output thereof between two levels when a voltage difference between the input signal and the output of said second inverting amplifying circuit goes above a first threshold value or goes below a second threshold value lower than the first threshold value.

4. The overcurrent detection circuit of claim 1, wherein:
said comparison circuit includes:
a differential amplifier circuit for amplifying a voltage difference between the input signal and the output of said second inverting amplifying circuit to generate an amplified voltage difference signal; and
a filter circuit for smoothing the amplified voltage difference signal to generate a smoothed voltage difference signal as the result of the comparison; and
said decision circuit includes:
a voltage-to-frequency converter for generating an oscillation signal with a frequency corresponding to a voltage of the smoothed voltage difference signal; and
a decision unit for detecting the overcurrent from the frequency of the oscillation signal.

5. The overcurrent detection circuit of claim 4, wherein said differential amplifier circuit includes an operational amplifier.

6. The overcurrent detection circuit of claim 4, wherein said filter circuit includes a capacitor.

7. The overcurrent detection circuit of claim 4, wherein said voltage-to-frequency converter is a voltage-controlled oscillator.

8. The overcurrent detection circuit of claim 1, wherein:
said comparison circuit includes:
a differential amplifier circuit for amplifying a voltage difference between the input signal and the output of said second inverting amplifying circuit to generate an amplified voltage difference signal; and
a filter circuit for smoothing the amplified voltage difference signal to generate a smoothed voltage difference signal as the result of the comparison; and
said decision circuit includes:
an analog-to-digital converter for converting the smoothed voltage difference signal to a digital signal; and
a decision unit for detecting the overcurrent from the digital signal.

9. The overcurrent detection circuit of claim 8, wherein said differential amplifier circuit includes an operational amplifier.

10. The overcurrent detection circuit of claim 8, wherein the filter circuit includes a capacitor.

11. The overcurrent detection circuit of claim 1, wherein the input signal is an audio signal supplied from an external source and said load is a loudspeaker.

12. A signal amplifying device, comprising:
a first inverting amplifying circuit for amplifying an input signal;
a second inverting amplifying circuit for amplifying an output of said first inverting amplifying circuit; and
an overcurrent detection circuit for detecting overcurrent due to an impedance fault between first and second input terminals of a load, said first input terminal of said load being connected to an output terminal of said first inverting amplifying circuit, and said second input terminal of said load being connected to an output terminal of said second inverting amplifying circuit, said overcurrent detection circuit including:
a comparison circuit for comparing a voltage of the input signal with a voltage of an output of said second inverting amplifying circuit, and generating a signal responsive to a result of the comparison; and
a decision circuit for detecting the overcurrent from the signal output by said comparison circuit.
